(19) United States
(12) Patent Application Publication
(10) Pub. No.: US 2004/0251778 A1
(43) Pub. Date: Dec. 16, 2004

(54) Actuator using piezoelectric element, and driving circuit for the same

(75) Inventor: Takayuki Hoshino, Osaka-shi (JP)

Correspondence Address: SIDLEY AUSTIN BROWN & WOOD LLP, 717 NORTH HARWOOD, SUITE 3400, DALLAS, TX, 75201, US

(73) Assignee: KONICA MINOLTA HOLDINGS INC.

(21) Appl. No.: 10/721,200

(22) Filed: Nov. 25, 2003

(30) Foreign Application Priority Data
Jun. 11, 2003 (JP) 2003/166366

(51) Int. Cl. H01L 41/09

(52) U.S. Cl. 310/317

(57) ABSTRACT

For an actuator that uses a piezoelectric element and drives a movable member by displacing a driving member in sawtooth-like fashion, there is provided an actuator driving circuit that can attain the desired performance while achieving a reduction in power consumption. The actuator moves the driving member and the movable member relative to each other by applying a sinusoidal wave signal to the piezoelectric element, which expands and contracts by application of a driving signal, and thereby causing expanding/contracting displacements expanding and contracting at respectively different speeds in the driving member, and the driving circuit for the actuator is characterized in that a capacitive element, which is connected in series to a parallel circuit containing an inductive element connected in parallel to the piezoelectric element, is provided between the piezoelectric element and a voltage applying circuit.

This application is based upon application No. 2003-166366 filed in Japan, the contents of which are hereby incorporated by reference.

### BACKGROUND OF THE INVENTION

1. Field of the Invention

The present invention relates to an actuator using a piezoelectric element which is suitable for driving an XY moving stage, a camera's photographic lens, and the like, and also relates to a driving circuit for such an actuator.

2. Description of the Related Art

Piezoelectric actuators for moving a movable object by utilizing a expansion and contraction of a piezoelectric element have been known in the art. FIG. 13 shows an example of a piezoelectric actuator using a fixed-type piezoelectric element. The piezoelectric actuator 101 is constructed by fixing one expanding/contracting end of the piezoelectric element 102 to a fixed wall of a frame and fixing a driving member 103 to the other end of the piezoelectric element 102. A movable member 104 is frictionally engaged on the driving member 103, and is thus movable along the driving member 103. When a drive voltage is applied from a voltage applying circuit 106, the piezoelectric element 102 contracts and expands in the axial direction of the driving member 103, and sawtooth-like expanding/contracting displacements expanding and contracting at respectively different speeds occur in the driving member 103 connected to one end of the piezoelectric element 102. This causes the movable member 104 to move in a designated direction along the driving member 103 by a distance equal to the difference in the amount of movement between the expanding and contracting displacements of the driving member 103 occurring at respectively different speeds.

The direction of movement of the movable member 104 is determined by the difference in the amount of movement between the expanding and contracting displacements of the driving member 103. For example, when the piezoelectric element 102 produces a displacement D such as shown in FIG. 14A that is, when the piezoelectric element 102 slowly expands in its thickness direction as indicated by 110 in the figure, the driving member 103 fixed to the piezoelectric element 102 is slowly displaced along its axial direction. In this case, as shown in FIG. 15B, the movable member 104 frictionally coupled to the driving member 103 moves together with the driving member 103 due to the frictional force acting between the driving member 103 and the movable member 104.

On the other hand, when the piezoelectric element 102 rapidly contracts in its thickness direction as indicated by 111 in the figure, the driving member 103 fixed to the piezoelectric element 102 is also rapidly displaced along its axial direction. In this case, as shown in FIG. 15C, the movable member 104 frictionally coupled to the driving member 103 remains substantially stationary thereon due to inertia overcoming the frictional coupling force. As a result, the movable member 104 moves to the right relative to the initial position shown in FIG. 15A.

By contrast, when the driving member 103 is displaced in such a manner as to slowly contract and rapidly expand as indicated by 112 and 113, respectively, in FIG. 14B, then the movable member 104 moves to the left in FIG. 13.

To cause sawtooth-like expanding/contracting displacements in the driving member 103 as shown in FIGS. 14A and 14B, generally a rectangular wave signal is applied to the piezoelectric element by using the voltage applying circuit 106 in conjunction with a microcomputer circuit 105. For example, Japanese Unexamined Patent Publication No. 2001-268951 discloses that a rectangular wave signal having a prescribed frequency is applied to the piezoelectric element 102 thereby causing sawtooth-like expanding/contracting displacements in the driving member 103.

The direction of the sawtooth-like expanding/contracting displacement of the driving member 103 is determined by the duty ratio of the rectangular wave signal that the driving circuit applies to the piezoelectric element 102. That is, by changing the duty ratio, the expanding/contracting displacement of the driving member 103 changes, and the direction and speed of movement of the movable member change. For example, when the duty ratio of the rectangular wave signal is 50%, the displacement of the driving member 103 is substantially sinusoidal, and the movable member 104 remains substantially stationary by just moving back and forth by only trace amounts. When the duty ratio of the rectangular wave signal is changed, for example, to 30%, the driving member 103 exhibits a substantially sawtooth-like displacement as shown in FIG. 14A, causing the movable member 104 to move to the right; on the other hand, when the duty ratio of the rectangular wave signal is changed to 70%, the driving member 103 exhibits a substantially sawtooth-like displacement such as shown in FIG. 14B, causing the movable member to move in the opposite direction.

However, since the driving signal that the driving circuit applies is an AC signal, there arises the problem that the power consumption of the piezoelectric element increases, as described below.

Japanese Unexamined Patent Publication No. H07-231683 discloses a technique for reducing the power consumption by connecting an inductive element in parallel to the piezoelectric element and producing an antiresonance between the inductive element and a damping capacitance of the piezoelectric element. FIG. 16 shows its circuit diagram.

As disclosed in the second Publication, the equivalent circuit of the piezoelectric element 102 is as indicated at 102 in FIG. 16. In the circuit of FIG. 16, the relationship shown in FIG. 17 exists between a inductance value L of a damping capacitor 108 and a frequency f of a AC voltage applied by the driving circuit. Accordingly, by setting a frequency of the drive voltage as the antiresonance condition (f₀), a combined impedance of a parallel circuit of the damping capacitor 108 and the inductive element 109 theoretically becomes infinitely large, and no current flows to the damping capacitor 108 or the inductive element 109, achieving a reduction in power consumption.

However, even the above driving circuit has had the problem that the power consumption is still large when a rectangular wave is used as the driving waveform. That is, as earlier described, the duty ratio of the rectangular wave must be changed in order to move the movable member 104 in both directions. When the duty ratio is changed, a DC component occurs in the rectangular wave signal applied to the piezoelectric element 102. More specifically, when the above time ratio is, for example, 50%, the DC component applied to the piezoelectric element 102 is 0 volt; on the other hand, when the duty ratio is 100%, a DC component of +E volts occurs, and when the duty ratio is 0%, a DC component of −E volts occurs.

In this way, when the duty ratio of the rectangular wave signal generated from the driving circuit is made higher or lower than 50% in order to change the direction and/or speed of movement of the movable member 104, a DC voltage component occurs in the rectangular wave output from the voltage applying circuit 106, and the impedance of the inductive element 109 decreases; as a result, an overcurrent flows in the inductive element 109 connected in parallel, and the power consumption increases, defeating the purpose of the parallel circuit.

More specifically, for a method that moves the movable member 104 by displacing the driving member 103 in sawtooth-like fashion as disclosed in Japanese Unexamined Patent Publication No. 2001-268951, no effective method has ever been proposed that could attain the desired performance while achieving a reduction in power consumption.

It is accordingly an object of the present invention to solve the above technical problem and provide an actuator driving circuit that can attain the desired performance while reducing the power consumption in an actuator that uses a piezoelectric element to move a movable member by subjecting a driving member to sawtooth-like expanding/contracting displacements expanding and contracting at respectively different speeds.

### SUMMARY OF THE INVENTION

To solve the above technical problem, the present invention provides an actuator driving circuit having the following configuration.

According to a first aspect of the present invention, there is provided an actuator driving circuit for use with an actuator that comprises a piezoelectric element which is caused to expand and contract by application of a driving signal, a driving member fixed to one end of the piezoelectric element along an expanding/contracting direction thereof, and a movable member frictionally engaging on the driving member, for moving the driving member and the movable member relative to each other by applying a rectangular wave signal to the piezoelectric element and thereby causing expanding/contracting displacements expanding and contracting at respectively different speeds in the driving member, the driving circuit comprising:

a parallel circuit containing an inductive element connected in parallel to the piezoelectric element; and

a capacitive element, connected in series to the parallel circuit, for removing an DC component of the rectangular wave signal, wherein

the parallel circuit and the capacitive element are provided between the piezoelectric element and a voltage applying circuit for applying the rectangular wave signal to the piezoelectric element.

Preferably, in the first aspect, the capacitive element is chosen to have a capacitance value higher than a value of damping capacitance of the piezoelectric element, and more specifically, the capacitance value of the capacitive element is set so that a ratio of a voltage applied across the piezoelectric element to a voltage applied across the capacitive element becomes larger than 9:1.

Also preferably, in the first aspect, the inductive element is set to have an inductance value that produces an antiresonance with the damping capacitance of the piezoelectric element.

According to a second aspect of the present invention, there is provided an actuator driving circuit for use with an actuator that comprises a piezoelectric element which is caused to expand and contract by application of a driving signal, a driving member fixed to one end of the piezoelectric element along an expanding/contracting direction thereof, and a movable member frictionally engaging on the driving member, for moving the driving member and the movable member relative to each other by applying a rectangular wave signal to the piezoelectric element and thereby causing expanding/contracting displacements expanding and contracting at respectively different speeds in the driving member, wherein

a series circuit containing a capacitive element for removing an DC component of the rectangular wave signal and an inductive element connected in series thereto is connected in parallel to the piezoelectric element in such a manner as to interpose between the piezoelectric element and a voltage applying circuit for applying the rectangular wave signal to the piezoelectric element.

In the second aspect, by connecting the capacitive element, the combined impedance of the driving circuit as a whole increases, and thus it becomes possible to reduce an overcurrent associated with the DC component of the rectangular wave signal that occurs when the duty ratio is changed.

Preferably, in the second aspect, the inductive element is set to have an inductance value that produces an antiresonance with damping capacitance of the piezoelectric element.

According to a third aspect of the present invention, there is provided an actuator driving circuit for use with an actuator that comprises an element array constructed by connecting a plurality of piezoelectric elements, each expanding and contracting by application of a driving signal, along an expanding/contracting direction thereof; a driving member fixed to one end of the element array along the expanding/contracting direction; and a movable member frictionally engaging on the driving member, for moving the driving member and the movable member relative to each other by applying an AC voltage to each of the piezoelectric elements in the element array and thereby causing expanding/contracting displacements expanding and contracting at respectively different speeds in the driving member, the driving circuit comprising:

a voltage applying circuit which, by dividing the element array into a plurality of piezoelectric element units having a piezoelectric element, for applying a first sinusoidal wave signal to the piezoelectric element in a first piezoelectric element unit of the piezoelectric element unit and for applying an n-th sinusoidal wave signal of a frequency n times a frequency of the first sinusoidal wave signal to a piezoelectric element in an n-th piezoelectric element unit, where n is an integer larger than 1; and

an inductive element connected in parallel to each of the plurality of piezoelectric elements and between the voltage applying circuit and the element array.

In the above configuration, the element array can be caused to produce sawtooth-like displacements by applying sinusoidal wave drive signals of different frequencies to the respective piezoelectric elements forming the plurality of piezoelectric element units. Accordingly, the driving member can be displaced in sawtooth-like fashion without using a rectangular wave drive signal, and thus the power consumption can be prevented from increasing due to the DC component occurring when the duty ratio of the rectangular wave is changed.

Preferably, in the third aspect, the element array is divided into two piezoelectric element units.

Also preferably, in the third aspect, the element array having a first piezoelectric element unit and a second piezoelectric element,

a second sinusoidal wave signal applied to a piezoelectric element in the second piezoelectric element unit is a sinusoidal wave signal whose amplitude is one quarter of a amplitude of the first sinusoidal wave signal applied to a piezoelectric element in the first piezoelectric element unit, and whose phase is coincident with the phase of the first sinusoidal wave signal.

Further preferably, in the third aspect, the element array having a first piezoelectric element unit and a second piezoelectric element, and a ratio of a length of the first piezoelectric element unit to a length of the second piezoelectric element unit along the expanding/contracting direction is 4:1.

According to a fourth aspect of the present invention, there is provided an actuator comprising:

a piezoelectric element which is caused to expand and contract by application of a driving signal;

a driving member fixed to one end of the piezoelectric element along an expanding/contracting direction thereof;

a movable member frictionally engaging on the driving member;

a voltage applying circuit for applying a rectangular wave signal to the piezoelectric element; and

a parallel circuit containing an inductive element connected in parallel to the piezoelectric element, and a capacitive element, connected in series to the parallel circuit, for removing an DC component of the rectangular wave signal, the parallel circuit and the capacitive element being provided between the voltage applying circuit and the piezoelectric element, wherein

the actuator moves the driving member and the movable member relative to each other by applying the rectangular wave signal to the piezoelectric element and thereby causing expanding/contracting displacements expanding and contracting at respectively different speeds in the driving member.

According to a fifth aspect of the present invention, there is provided an actuator comprising:

a piezoelectric element which is caused to expand and contract by application of a driving signal;

a driving member fixed to one end of the piezoelectric element along an expanding/contracting direction thereof;

a movable member frictionally engaging on the driving member;

a voltage applying circuit for applying a rectangular wave signal to the piezoelectric element; and

a series circuit containing a capacitive element for removing an DC component of the rectangular wave signal and an inductive element connected in series thereto, the series circuit being provided between the voltage applying circuit and the piezoelectric element, wherein

the actuator moves the driving member and the movable member relative to each other by applying the rectangular wave signal to the piezoelectric element and thereby causing expanding/contracting displacements expanding and contracting at respectively different speeds in the driving member.

According to a sixth aspect of the present invention, there is provided an actuator comprising:

an element array constructed by connecting a plurality of piezoelectric elements, each expanding and contracting by application of a driving signal, along an expanding/contracting direction thereof;

a driving member fixed to one end of the element array along the expanding/contracting direction thereof;

a movable member frictionally engaging on the driving member;

a voltage applying circuit which, by dividing the element array into a plurality of piezoelectric element units each consisting of one or more piezoelectric elements, applies a first sinusoidal wave signal to each piezoelectric element in a first piezoelectric element unit and applies an n-th sinusoidal wave signal of a frequency n times the frequency of the first sinusoidal wave signal to each piezoelectric element in an n-th piezoelectric element unit, where n is an integer larger than 1; and

an inductive element connected in parallel to each of the plurality of piezoelectric elements and between the voltage applying circuit and the element array, wherein

the actuator moves the driving member and the movable member relative to each other by applying an AC voltage to each of the piezoelectric elements in the element array and thereby causing expanding/contracting displacements expanding and contracting at respectively different speeds in the driving member.

### BRIEF DESCRIPTION OF THE DRAWINGS

These and other objects and features of the present invention will become clear from the following description taken in conjunction with the proffered embodiments thereof with reference to the accompanying drawings:

FIG. 1 is a diagram schematically showing a construction of a piezoelectric actuator according to a first embodiment of the present invention;

FIG. 2 is a block diagram showing a driving circuit for the piezoelectric actuator of FIG. 1;

FIG. 3 is a diagram schematically showing a construction of a piezoelectric actuator according to a second embodiment of the present invention;

FIG. 4 is a block diagram showing a driving circuit for the piezoelectric actuator of FIG. 3;

FIG. 5A is a diagram schematically showing a construction of a piezoelectric actuator using a piezoelectric element according to a third embodiment of the present invention;

FIG. 5B is a diagram showing a first modified example of the piezoelectric actuator according to the third embodiment;

FIG. 6 is a diagram showing a second modified example of the piezoelectric actuator according to the third embodiment;

FIG. 7 is a diagram showing a third modified example of the piezoelectric actuator according to the third embodiment;

FIG. 8 is a diagram showing the displacements of the respective piezoelectric elements forming a piezoelectric element array and the displacement over time of the piezoelectric element array as a whole;

FIG. 9 is a circuit diagram of a driving circuit for generating a rectangular wave signal;

FIGS. 10A, 10B, 10C, 10D, and 10E are timing charts for explaining the operation when a duty ratio is 50%;

FIG. 11 is a perspective view showing a construction of a lens driving device that uses the piezoelectric actuator of the present invention;

FIG. 12 is a perspective view showing a construction of an XY moving stage that uses the piezoelectric actuator of the present invention;

FIG. 13 is a diagram showing a construction of a prior art piezoelectric actuator using a fixed-type piezoelectric element;

FIGS. 14A and 14B are diagrams showing the amounts of displacements of a driving member in the prior art piezoelectric actuator as a function of time;

FIGS. 15A, 15B, and 15C are diagrams for explaining a principle of driving the prior art piezoelectric actuator;

FIG. 16 is a circuit diagram showing a configuration of a driving circuit for the prior art piezoelectric actuator; and

FIG. 17 is a graph showing a relationship between the frequency f of the AC voltage applied by the driving circuit and the inductance value L of a damping capacitor in the piezoelectric actuator having the driving circuit of FIG. 14.

### DESCRIPTION OF THE PREFERRED EMBODIMENTS

Before the description of the present invention proceeds, it is to be noted that like parts are designated by like reference numerals throughout the accompanying drawings.

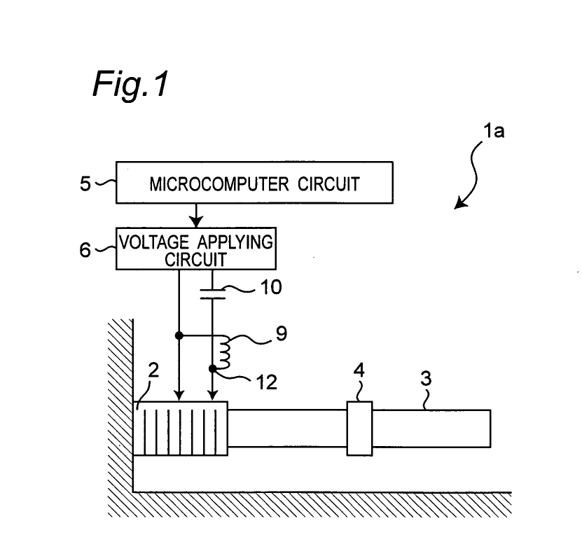

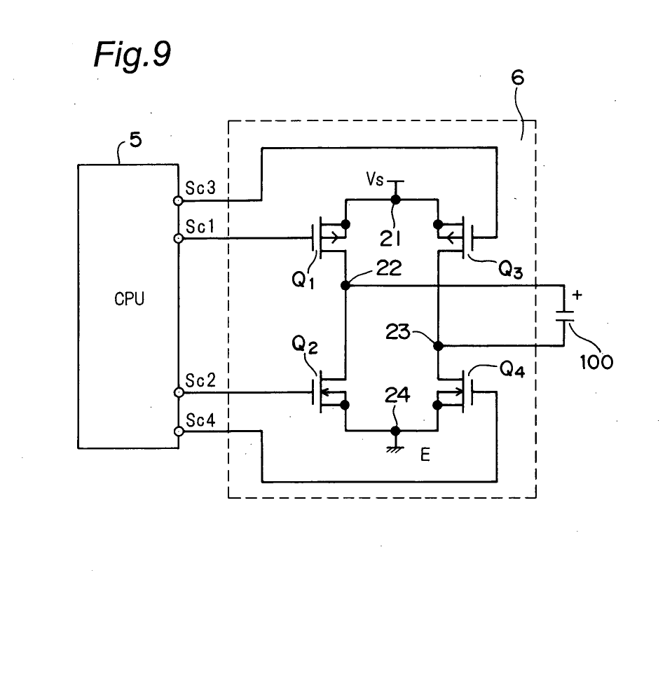

A piezoelectric actuator according to a first embodiment has the construction shown, for example, in FIG. 1, and comprises a driving member 3 connected to a piezoelectric element 2 along the expanding/contracting direction thereof, and a movable member 4 frictionally engaging on the driving member 3. The piezoelectric element 2 is connected to an output terminal 100 of a voltage applying circuit 6, shown in FIG. 9, which generates a rectangular wave voltage by receiving signals from a microcomputer circuit 5.

FIG. 9 shows the detailed configuration of the voltage applying circuit 6. The voltage applying circuit 6 includes four switch elements Q1, Q2, Q3, and Q4 connected to the CPU 5 of the control circuit, and applies a voltage between the terminals of the piezoelectric element 2.

The switch elements Q1 to Q4 are MOSFETs, whose gates are connected to the respective terminals Sc1 to Sc4 of the CPU 5 and are each supplied with a Hi or Lo signal. The switch elements Q1 and Q3 are P-channel FETs, in which the channel between the source and drain becomes ON (conducting) when a Lo signal is applied to the gate, and becomes OFF (nonconducting) when a Hi signal is applied. The switch elements Q2 and Q4 are N-channel FETS, in which the channel between the source and the drain becomes ON (conducting) when a Hi signal is applied to the gate, and becomes OFF (nonconducting) when a Lo signal is applied.

The sources of the switch elements Q1 and Q3 are both connected via a node 21 to a power supply voltage Vs. The drain of the switch element Q1 is connected via a node 22 to the drain of the switch element Q2. The drain of the switch element Q3 is connected via a node 23 to the drain of the switch element Q4. The sources of the switch elements Q2 and Q4 are both grounded via a node 24. The terminals of the piezoelectric element 102 are respectively connected to the nodes 22 and 23.

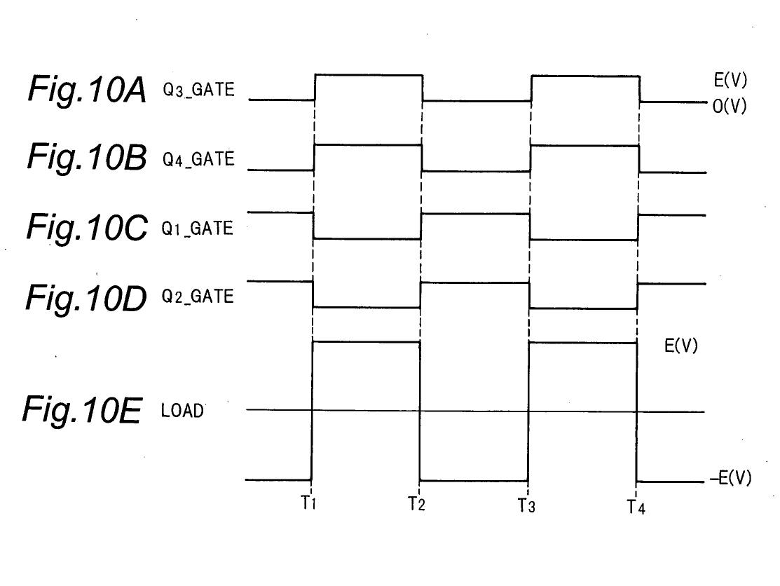

FIGS. 10A to 10E are timing diagrams for explaining the operation of the voltage applying circuit 6 when the duty ratio is 50%. When the switch elements Q1 and Q4 are conducting and the switch elements Q2 and Q3 are nonconducting in the voltage applying circuit 6, voltage E is applied to the piezoelectric element 2 (T1 to T2, T3 to T4). Conversely, when the switch elements Q2 and Q3 are conducting and the switch elements Q1 and Q4 are nonconducting, voltage −E is applied to the piezoelectric element 2 (T2 to T3). By repeating this operation with a prescribed period, the microcomputer circuit 5 applies a rectangular wave pulse signal to the piezoelectric element 2. The duty ratio can be changed by changing the ratio between the time that the switch elements Q1 and Q4 are conducting and the switch elements Q2 and Q3 are nonconducting and the time that the switch elements Q2 and Q3 are conducting and the switch elements Q1 and Q4 are nonconducting. The duty ratio and the frequency of the rectangular wave pulse signal in the driving circuit 5 are controlled through timing control by the microcomputer 5 in response to a clock signal from a clock generating circuit not shown.

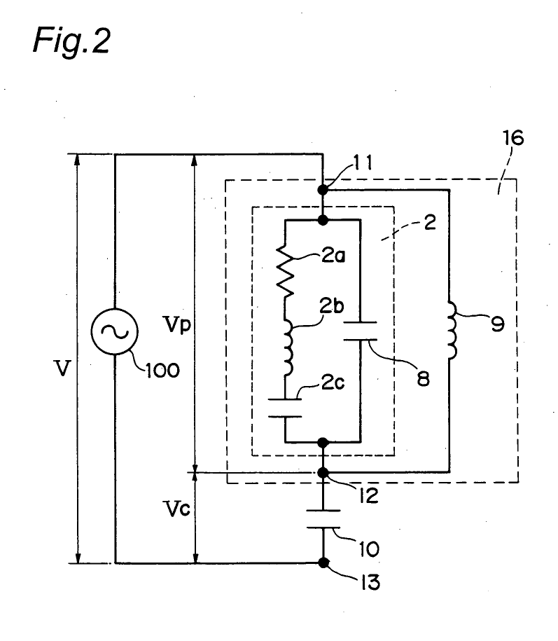

FIG. 2 is a block diagram showing a driving circuit for the piezoelectric actuator of the above-described embodiment. In FIG. 2, reference numeral 2 indicates the piezoelectric element represented by an equivalent circuit, 8 indicates a damping capacitor in the piezoelectric element, 9 indicates an inductive element, and 10 indicates a capacitive element. The driving circuit la is connected, for example, to the output terminal 100 of the driving circuit shown in FIG. 9.

The driving circuit la is constructed by connecting the capacitive element 10 in series to the parallel circuit containing the piezoelectric element 2 and the inductive element 9 connected in parallel. The capacitive element 10 shuts off the DC component of the rectangular wave. Accordingly, if any route is taken between terminals 11 to 13, the DC component can be shut off, and the current flowing to the piezoelectric element 2 can thus be reduced.

In the driving circuit 1a shown in FIG. 1, the combined impedance Z1 of the circuit consisting of the damping capacitor 8, inductive element 9, and capacitive element 10 can be expressed as shown by equation (1) below.

$$Z1 = \frac{1}{j ω Co} \cdot \frac{1 - {ω}^{2} L ( C + Co )}{1 - {ω}^{2} LC} \qquad ( 1 )$$

In equation (1), j is the angular velocity, ω is the angular frequency, C is the capacitance value of the damping capacitor 8, L is the inductance value of the inductive element 9, and Co is the capacitance value of the capacitive element 10.

When the drive frequency f of the drive voltage is set so as to satisfy the antiresonance condition, from the above equation (1) the combined impedance Z1 at the drive frequency f becomes infinitely large; this serves to prevent an overcurrent from flowing to the piezoelectric element, and achieves the effect of reducing the power consumption.

For the DC component (ω=0) also, equation (1) becomes infinitely large, so that the overcurrent of the DC component flowing in the driving circuit 1a becomes zero. This achieves the effect of reducing the power consumption.

The capacitance value Co of the capacitive element 10 is set sufficiently large compared with the capacitance value C of the damping capacitor 8. The reason is as follows: Since the voltage Vp applied to the piezoelectric element 2 and the voltage Vc applied to the capacitive element 10 are in such a relationship that divides the output voltage V of the driving circuit between the voltage Vp and the voltage Vc, the voltage Vp applied to the piezoelectric element 2 can be made large by setting the capacitance value Co of the capacitive element 10 sufficiently large, and performance degradation of the driving circuit can thus be prevented. Since the amount of displacement of the piezoelectric element changes with the voltage Vp applied to the piezoelectric element 2, it is desirable to make the setting so that the voltage Vp applied to the piezoelectric element 2 becomes as large as possible and to determine the capacitance value Co of the capacitive element 10 so that the ratio of Vp to Vc becomes larger than 9:1.

Further, in the case of a rectangular wave, the output contains harmonics but, for the harmonics also, the effect of reducing the power consumption can be realized. For example, when the capacitance value C of the damping capacitor 8 is 0.1 μF, the inductance value L of the inductive element 9 is 80 μH, and the capacitance value Co of the capacitive element 10 is 1 μF, then the drive frequency f is 56.3 kHz from equation (2) showing the antiresonance condition.

$$f = \frac{1}{2 π \sqrt{LC}} \qquad ( 2 )$$

In equation (2), C is the capacitance value of the damping capacitor 8, and L is the inductance value of the inductive element 9.

For the fundamental wave component of the drive frequency, the impedance Zc of the damping capacitor 8 is 28.3 Ω, while the combined impedance Z1 is infinitely large. For the second harmonic of the drive frequency, the impedance Zc of the damping capacitor 8 is 14.1 Ω and the combined impedance Z1 is 20.3 Ω, and for the third harmonic of the drive frequency, the impedance Zc of the damping capacitor 8 is 9.5 Ω and the combined impedance Z1 is 11.5 Ω; in either case, the combined impedance Z1 is higher than the impedance Zc of the damping capacitor 8.

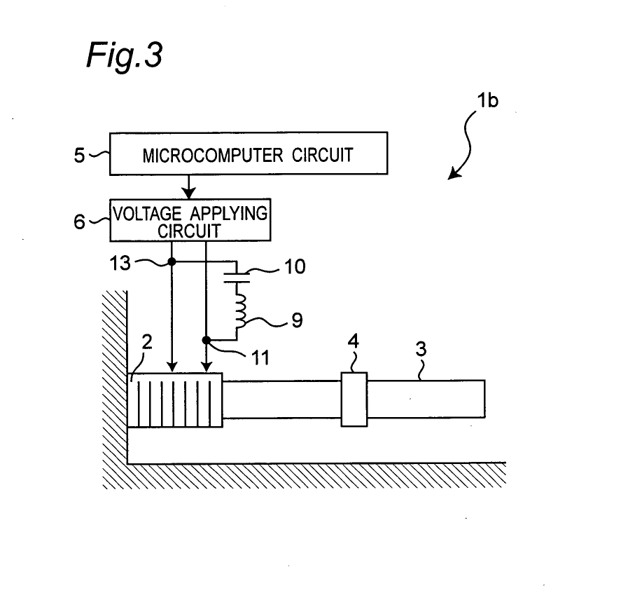

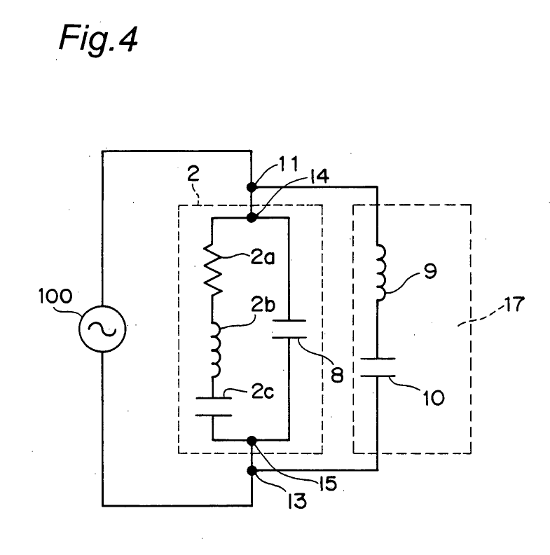

FIG. 3 is a diagram showing the construction of a piezoelectric actuator according to a second embodiment of the present invention, and FIG. 4 is a block diagram showing a driving circuit for the piezoelectric actuator of FIG. 3. The construction of the piezoelectric actuator is the same as that of the first embodiment. The driving circuit of the second embodiment is constructed by connecting in parallel with the piezoelectric element 2 a series circuit 17 containing the inductive element 9 and the capacitive element 10 connected in series. The capacitive element 10 shuts off the DC component of the rectangular wave. That is, if any route is taken between the terminals 11 to 13, the DC component can be shut off, and the current flowing to the piezoelectric element 2 can thus be reduced.

In the driving circuit shown in FIG. 4, the combined impedance Z2 of the circuit consisting of the damping capacitor 8, inductive element 9, and capacitive element 10 can be expressed as shown by equation (3) below.

$$Z2 = \frac{1}{j ω Co} \cdot \frac{1 - {ω}^{2} LCo}{( 1 + \frac{C}{Co} ) - {ω}^{2} LC} \qquad ( 3 )$$

In equation (3), j is the angular velocity, ω is the angular frequency, C is the capacitance value of the damping capacitor 8, L is the inductance value of the inductive element 9, and Co is the capacitance value of the capacitive element 10.

When the drive frequency f of the drive voltage is set so as to satisfy the antiresonance condition, from the above equation (3) the combined impedance Z2 at the drive frequency f becomes infinitely large; this serves to prevent an overcurrent from flowing to the piezoelectric element 2, and achieves the effect of reducing the power consumption.

For the DC component (ω=0) also, equation (3) becomes infinitely large, so that the overcurrent of the DC component flowing in the driving circuit 1b becomes zero. This achieves the effect of reducing the power consumption. Furthermore, since the capacitive element 10 and the inductive element 9 are not in a voltage dividing relationship, the voltage applied between the terminals 14 and 15 of the piezoelectric element 2 is equal to the voltage at the output 100 of a series circuit 17; as a result, performance degradation of the piezoelectric actuator does not occur.

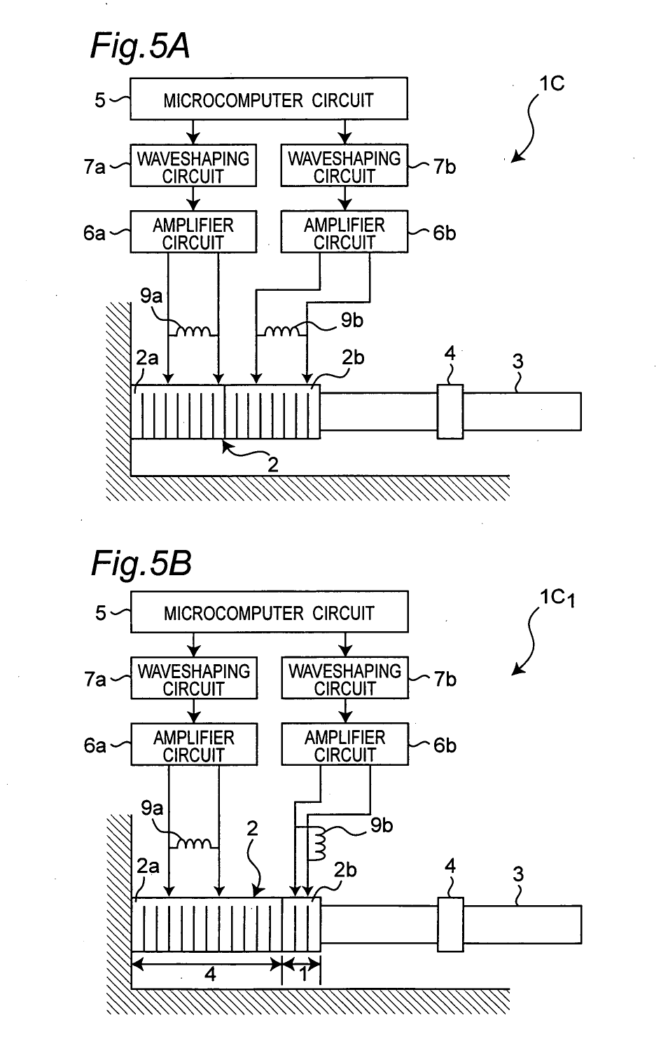

FIGS. 5A and 5B are a diagrams schematically showing the construction of a piezoelectric actuator according to a third embodiment of the present invention. In the piezoelectric actuator shown in FIG. 5A, two piezoelectric elements 2a and 2b having the same characteristics are bonded together along the expanding/contracting direction thereof to form a piezoelectric element array 2, and one end of the piezoelectric element array 2 is fixed to a fixed wall of a frame, while to the other end is fixed a driving member 3. A movable member 4 is frictionally engaged on the driving member 3, and is thus movable along the driving member 3.

Digital signals generated from the microcomputer circuit 5 are waveshaped by waveshaping circuits 7a and 7b into sinusoidal waveforms having prescribed shapes as will be described later, and these sinusoidal waveforms are amplified by amplifier circuits 6a and 6b and applied to the respective piezoelectric elements 2a and 2b. That is, the driving signals applied to the respective piezoelectric elements 2a and 2b are signals of sinusoidal waveform containing no DC component.

The sinusoidal voltages applied to the respective piezoelectric elements 2a and 2b are such that, when the sinusoidal voltage applied to one piezoelectric element 2a is denoted as the first sinusoidal voltage, a sinusoidal voltage whose frequency is twice that of the first sinusoidal voltage, and whose amplitude is one quarter of that of the first sinusoidal voltage, is applied to the other piezoelectric element 2b in such a manner that no phase difference occurs between the two sinusoidal voltages.

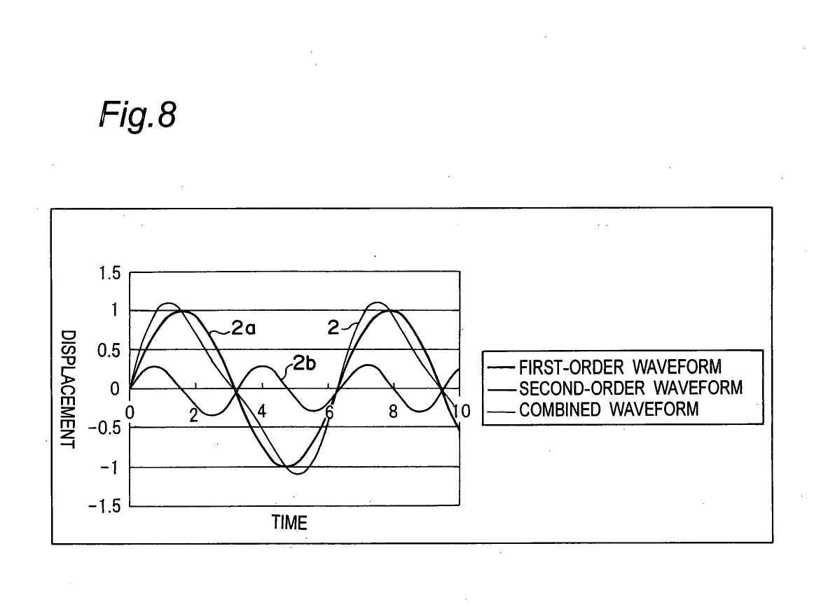

FIG. 8 shows the displacements of the respective piezoelectric elements 2a and 2b and the displacement over time of the piezoelectric element array as a whole. The respective piezoelectric elements 2a and 2b produce displacements as shown in FIG. 8 in accordance with the sinusoidal voltages applied to the piezoelectric elements 2a and 2b. Since the piezoelectric element array 2 is constructed by connecting the two piezoelectric elements 2a and 2b along the expanding/contracting direction thereof, the displacement of the piezoelectric element array 2 as a whole is represented by the combined waveform of the two piezoelectric elements 2a and 2b, and hence a sawtooth-like waveform as shown in FIG. 8. As a result, the driving member 3 fixed to the piezoelectric element array 2 exhibits sawtooth-like displacements expanding and contracting at respectively different speeds, and the movable member 4 can thus be moved.

Since the driving signals applied to the respective piezoelectric elements consist only of sinusoidal wave components that contain no DC component, the power consumption can be reduced drastically by connecting the inductive element in parallel to each piezoelectric element. Furthermore, since the voltage applied to each piezoelectric element does not drop, performance degradation of the piezoelectric actuator does not occur.

Modified examples of the piezoelectric actuator according to the third embodiment will be described. In a first modified example of the piezoelectric actuator, the signals applied to the respective piezoelectric elements are identical to each other, but the lengths of the respective piezoelectric elements forming the piezoelectric element array are different from each other, as shown in FIG. 5B. That is, the ratio of the length of the piezoelectric element 2a to the length of the piezoelectric element 2b is set to 4:1, and when the same sinusoidal drive signal is applied to the two piezoelectric elements, the piezoelectric element array 2 produces sawtooth-like displacements expanding and contracting at respectively different speeds. In this case also, since the sinusoidal drive signal contains no DC component, the power consumption can be prevented from increasing excessively due to the DC component.

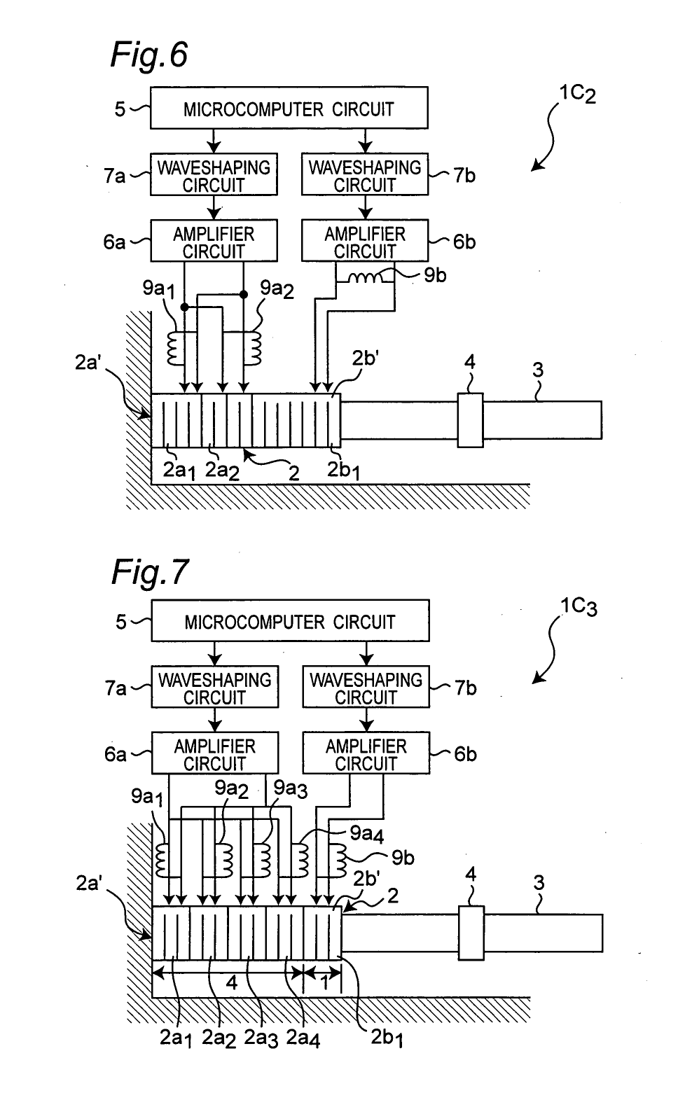

A second modified example of the piezoelectric actuator according to the third embodiment will be described with reference to FIG. 6. In the piezoelectric actuator 1c₂ of this modified example, the piezoelectric element array 2 comprises two piezoelectric element units 2a′ and 2b′, as shown in FIG. 6. The piezoelectric element unit 2a′ is constructed using two piezoelectric elements 2a₁ and 2a₂, while the piezoelectric element unit 2b′ is constructed using only one piezoelectric element 2b₁. The length of each of the piezoelectric elements 2a₁ and 2a₂ in the piezoelectric element unit 2a′ is one half that of the piezoelectric element 2b₁ in the piezoelectric element unit 2b′, that is, the piezoelectric element unit 2a′ has the same length as the piezoelectric element unit 2b′. The microcomputer circuit 5 applies the sinusoidal wave shown at 2a in FIG. 8 to each of the piezoelectric elements 2a₁ and 2a₂ in the piezoelectric element unit 2a′, and the sinusoidal wave shown at 2b in FIG. 8 to the piezoelectric element 2b₁ in the piezoelectric element unit 2b′. As a result, the piezoelectric element array 2 produces sawtooth-like displacements expanding and contracting at respectively different speeds, as shown by 2 in FIG. 8. In this case also, since the sinusoidal drive signals contain no DC component, the power consumption can be prevented from increasing excessively due to the DC component.

A third modified example of the piezoelectric actuator according to the third embodiment will be described with reference to FIG. 7. In the piezoelectric actuator 1c₃ of this modified example, the piezoelectric element array 2 comprises two piezoelectric element units 2a′ and 2b′, as shown in FIG. 7. The piezoelectric element unit 2a′ is constructed using four piezoelectric elements 2a₁, 2a₂, 2a₃, and 2a₄, while the piezoelectric element unit 2b′ is constructed using only one piezoelectric element 2b₁. The piezoelectric elements 2a₁, 2a₂, 2a₃, 2a₄, and 2b₁ are identical in construction, and therefore, the ratio of the length of the piezoelectric element unit 2a′ to the length of the piezoelectric element unit 2b′ is 4:1. The microcomputer circuit 5 applies identical sinusoidal drive signals to the respective piezoelectric element units 2a′ and 2b′; as a result, the piezoelectric element array 2 produces sawtooth-like displacements expanding and contracting at respectively different speeds. In this case also, since the sinusoidal drive signals contain no DC component, the power consumption can be prevented from increasing excessively due to the DC component.

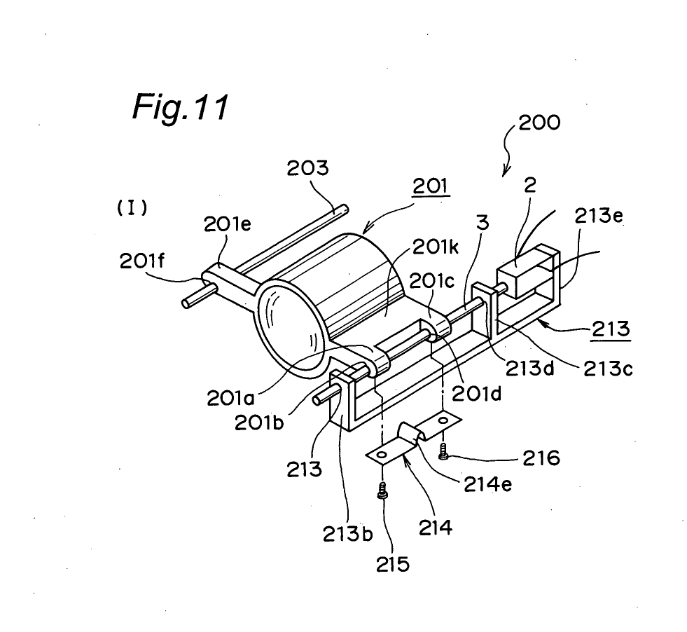

The piezoelectric actuator according to each of the above embodiments may be used as a lens driving device 200, as shown in FIG. 11. The lens driving device is used to finely drive a lens barrel 201 holding a lens therein, for example, for focusing. Reference numeral 203 indicates a guide bar which supports the lens barrel and guides it along the direction of the optical axis. The guide bar 203 is provided passing through a fork 201f formed in a supporting portion 201e extending from the lens barrel 201, and thus supports and guides the lens barrel 201 thereon.

The piezoelectric actuator 1 (1a, 1b, 1c, 1c₁) according to each of the above embodiments is supported on a supporting member 213. The driving member 3 is supported by being passed through holes 201b and 201d formed at both ends 201a and 201c of a protruding portion 201k protruding from the lens barrel 201 in a direction opposite to the supporting portion 201e. The driving shaft is also inserted in rising portions 213b and 213c of the supporting member, and is thus supported in such a manner as to be movable along its axial direction. The rear end of the driving member 3 is fixed to the piezoelectric element 2. The rear end of the piezoelectric element 2 is fixed to another rising portion 213e of the supporting member 213.

Further, a plate spring 214 is attached to the respective ends 201a and 201c of the lens barrel 201 with screws 215 and 216 from the underside in the figure. A frictional part 214c protruding upward in the figure is formed substantially centered on the plate spring 214; with the frictional part contacting the driving member 3, friction is generated between the lens barrel 201 and the driving member 3 for frictional engagement so that the lens barrel 201 can be driven.

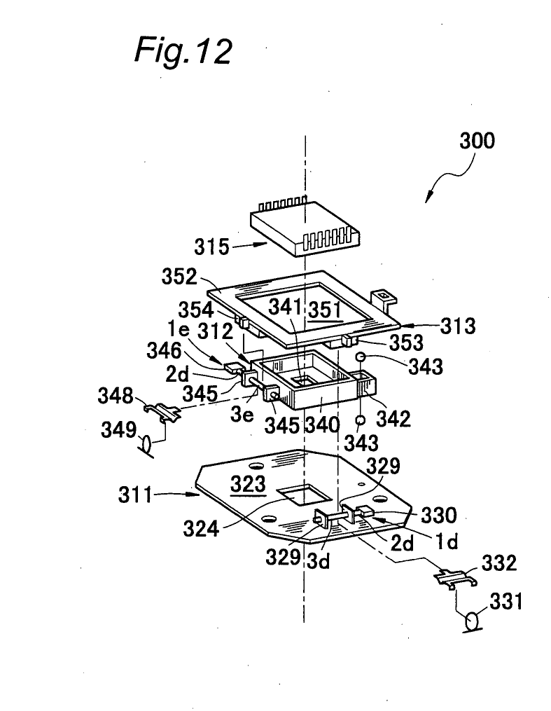

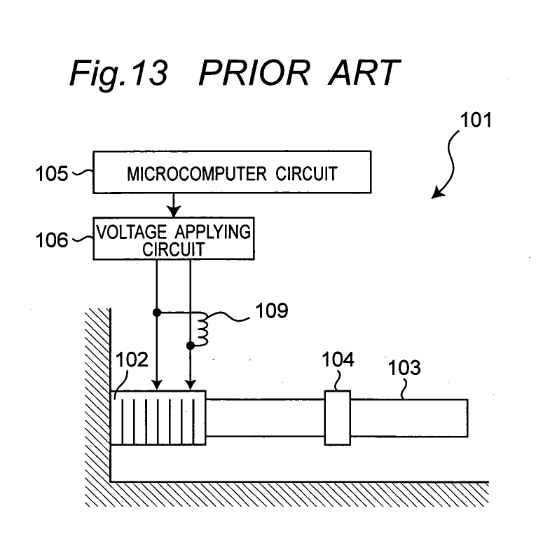

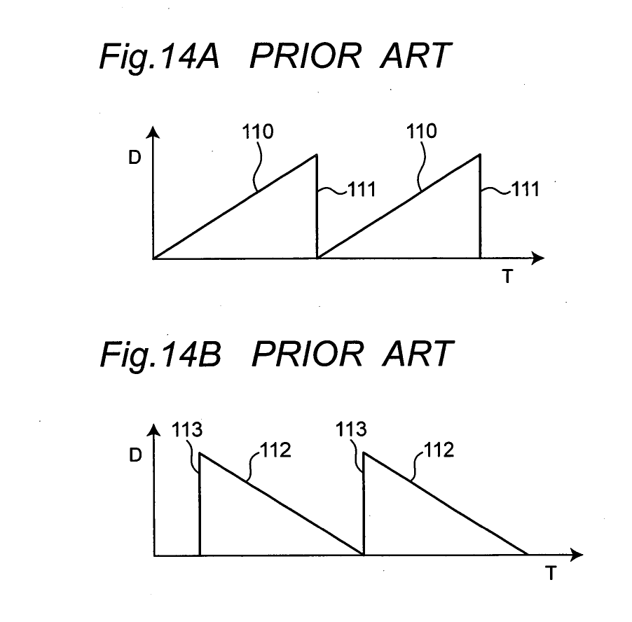

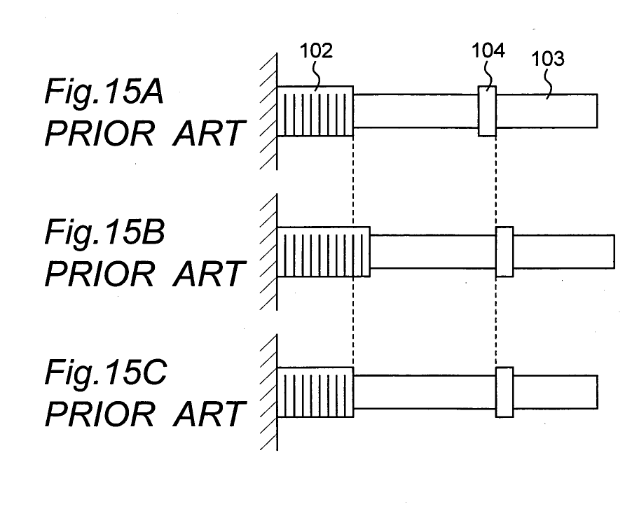

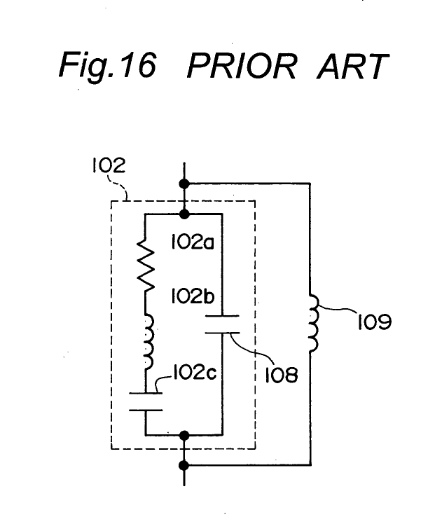

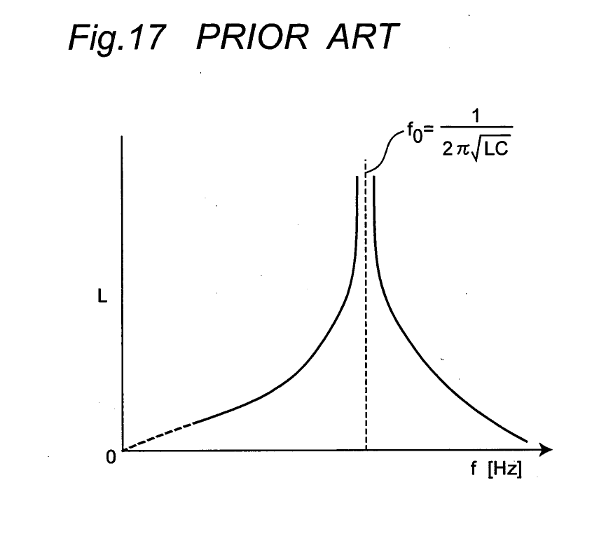

The piezoelectric actuator according to each of the above embodiments may be also used as an actuator for an XY moving stage 300, as shown in FIG. 12. The XY moving stage shown in FIG. 10 is used to finely move an imaging device horizontally in the directions of two axes to correct for camera shake or the like.

The XY moving stage comprises a base member 311 as the base of the stage, a first stage 313 which can moves in a horizontal direction relative to the base member 311, a second stage 312 which moves in a direction perpendicular to the moving direction of the first stage 313, and the imaging device 315 fixed to the second stage 312.

The base member 311, the first stage 313, and the second stage 312, which support the imaging device 315 in movable fashion, are located in such a manner as to encircle the imaging device 315.

The base member 311 is a plate member lying in a plane substantially perpendicular to the direction of the optical axis indicated by a semi-dashed line, and comprises a metal frame 323 having a large hole 324 at its center through which the optical axis passes. Rod supporting arms 329 and positioning arms (not shown) for supporting the piezoelectric actuator 1d (1a, 1b, 1c, 1c₁) according to each of the above embodiments are provided in protruding fashion on the base member 311. The rod supporting arms 329 fix the piezoelectric element 2d to one end of the driving member 3d.

The first stage 313 is located on the downstream side of the base member 311 as viewed in the direction of the optical axis. The first stage 313 comprises a rectangular aluminum frame 352 provided with an opening 351 for accommodating the second stage 312 in the substantially same plane. The first stage 313 includes a first contacting portion 353 which brought into contact with against the driving member 3 of the first actuator id fixed to the base member 311, and a second contacting portion 354 which brought into contact with against a driving member 3e of a second actuator 1e fixed to the second stage 312 to be described later.

The first contacting portion 353 supports the driving member 3d of the first actuator 1d from both the upper and lower sides thereof in collaboration with another member consisting of a cap 332 and a spring 313, and is coupled to the first actuator 1d in such a manner as to be slidable along the driving member 3d. The cap 332 is fixed to the first contacting portion 353 of the first stage, by having one end engaged with the first stage 331 and the other end pulled by the holding spring 331 while pressing the center portion against the driving member 3d.

The second stage 312 is a box member 340 made of an electrically conductive resin and having an opening 341 in its bottom, and holds thereon the imaging device 315 and the second actuator 1e. The second actuator 1e is fixed to the second stage 312. More specifically, the second actuator 1e is bonded to supporting arms 345 provided on a side portion of the box member 340. The second actuator 1e is supported with the front end and rear end (the end fixed to the piezoelectric element 2e) of the driving member 3e being engaged with the two rod supporting arms provided on the second stage 312.

The second actuator 1e fixed to the second stage 312 is held between the second contacting portion 354 of the first stage 313 and a cap 348. As a result, the second stage 312 is frictionally coupled by being positioned within the opening 351 of the first stage 313. A holding spring 349 is used to fix the second contacting portion 354 and the cap 348 together.

As described above, according to the piezoelectric actuator of each of the above embodiments, the effect of reducing the power consumption is achieved without degrading performance for a piezoelectric actuator driving circuit that drives the movable member by displacing the driving member in sawtooth-like fashion.

According to the first and fourth aspects of the present invention, since the DC component that occurs when the duty ratio of the rectangular wave is changed can be shut off by the capacitive element, an excessive DC component current can be prevented from flowing to the piezoelectric element, and thus, excessive power consumption due to the DC component current can be prevented.

According to the second and fifth aspects of the present invention, since the DC component that occurs when the duty ratio of the rectangular wave is changed can be shut off by the capacitive element, excessive power consumption due to the DC component current can be prevented. Furthermore, since the voltage applied to the piezoelectric element does not drop, performance degradation of the actuator does not occur.

According to the third and sixth aspects of the present invention, since sawtooth-like displacements can be imparted to the driving member by using a sinusoidal wave signal, there is no need to use a rectangular wave signal. This serves to prevent the power consumption from increasing due to an excessive flow of the DC component associated with the rectangular wave signal.

The present invention is not limited to the above-described embodiments, but can be carried out in various other forms.

For example, in the third embodiment, the number of piezoelectric elements forming the piezoelectric element array need not be limited to two, but three or more elements may be used. However, since the actuator size increases as the number of piezoelectric elements forming the piezoelectric element array increases, it is preferable to limit the number of elements to within the range of about 2 to 10.

Although the present invention has been fully described in connection with the preferred embodiments thereof with reference to the accompanying drawings, it is to be noted that various changed and modifications are apparent to those skilled in the art. Such changes and modifications are to be understood as included within the scope of the present invention as defined by the appended claims unless they depart therefrom.

What is claimed is:

1. An actuator driving circuit for use with an actuator that comprises a piezoelectric element which is caused to expand and contract by application of a driving signal, a driving member fixed to one end of said piezoelectric element along an expanding/contracting direction thereof, and a movable member frictionally engaging on said driving member, for moving said driving member and said movable member relative to each other by applying a rectangular wave signal to said piezoelectric element and thereby causing expanding/contracting displacements expanding and contracting at respectively different speeds in said driving member, said driving circuit comprising:
a parallel circuit containing an inductive element connected in parallel to said piezoelectric element; and
a capacitive element, connected in series to said parallel circuit, for removing an DC component of said rectangular wave signal, wherein
said parallel circuit and said capacitive element are provided between said piezoelectric element and a voltage applying circuit for applying said rectangular wave signal to said piezoelectric element.

2. An actuator driving circuit as set forth in claim 1, wherein said capacitive element has a capacitance value larger than a value of damping capacitance of said piezoelectric element.

3. An actuator driving circuit as set forth in claim 1, wherein the capacitance value of said capacitive element is set so that a ratio of a voltage applied across said piezoelectric element to a voltage applied across said capacitive element becomes larger than 9:1.

4. An actuator driving circuit as set forth in claim 1, wherein said inductive element is set to have an inductance value that produces an antiresonance with a damping capacitance of said piezoelectric element.

5. An actuator driving circuit for use with an actuator that comprises a piezoelectric element which is caused to expand and contract by application of a driving signal, a driving member fixed to one end of said piezoelectric element along an expanding/contracting direction thereof, and a movable member frictionally engaging on said driving member, for moving said driving member and said movable member relative to each other by applying a rectangular wave signal to said piezoelectric element and thereby causing expanding/contracting displacements expanding and contracting at respectively different speeds in said driving member, wherein
a series circuit containing a capacitive element for removing an DC component of said rectangular wave signal and an inductive element connected in series thereto is connected in parallel to said piezoelectric element in such a manner as to interpose between said piezoelectric element and a voltage applying circuit for applying said rectangular wave signal to said piezoelectric element.

6. An actuator driving circuit as set forth in claim 5, wherein said inductive element is set to have an inductance value that produces an antiresonance with damping capacitance of said piezoelectric element.

7. An actuator driving circuit for use with an actuator that comprises: an element array constructed by connecting a plurality of piezoelectric elements, each expanding and contracting by application of a driving signal, along an expanding/contracting direction thereof; a driving member fixed to one end of said element array along said expanding/contracting direction; and a movable member frictionally engaging on said driving member, for moving said driving member and said movable member relative to each other by applying an AC voltage to each of said piezoelectric elements in said element array and thereby causing expanding/contracting displacements expanding and contracting at respectively different speeds in said driving member,
said driving circuit comprising:
a voltage applying circuit which, by dividing said element array into a plurality of piezoelectric element units each having a piezoelectric element, for applying a first sinusoidal wave signal to the piezoelectric element in a first piezoelectric element unit of the piezoelectric element array, and for applying an n-th sinusoidal wave signal of a frequency n times a frequency of said first sinusoidal wave signal to a piezoelectric element in an n-th piezoelectric element unit of the piezoelectric element array, where n is an integer larger than 1; and
an inductive element connected in parallel to each of said plurality of piezoelectric elements and between said voltage applying circuit and said element array.

8. An actuator driving circuit as set forth in claim 7, wherein said element array is divided into two piezoelectric element units.

9. An actuator driving circuit as set forth in claim 7, wherein said element array having a first piezoelectric element unit and a second piezoelectric element,
a second sinusoidal wave signal applied to a piezoelectric element in the second piezoelectric element unit is a sinusoidal wave signal whose amplitude is one quarter of a amplitude of said first sinusoidal wave signal applied to a piezoelectric element in the first piezoelectric element unit, and whose phase is coincident with the phase of said first sinusoidal wave signal.

10. An actuator driving circuit as set forth in claim 7, wherein said element array having a first piezoelectric element unit and a second piezoelectric element, and a ratio of a length of the first piezoelectric element unit to a length of the second piezoelectric element unit along said expanding/contracting direction is 4:1.

11. An actuator comprising:
a piezoelectric element which is caused to expand and contract by application of a driving signal;
a driving member fixed to one end of said piezoelectric element along an expanding/contracting direction thereof;
a movable member frictionally engaging on said driving member;
a voltage applying circuit for applying a rectangular wave signal to said piezoelectric element; and
a parallel circuit containing an inductive element connected in parallel to said piezoelectric element, and a capacitive element, connected in series to said parallel circuit, for removing an DC component of said rectangular wave signal, said parallel circuit and said capacitive element being provided between said voltage applying circuit and said piezoelectric element, wherein
said actuator moves said driving member and said movable member relative to each other by applying said rectangular wave signal to said piezoelectric element and thereby causing expanding/contracting displacements expanding and contracting at respectively different speeds in said driving member.

12. An actuator comprising:
a piezoelectric element which is caused to expand and contract by application of a driving signal;
a driving member fixed to one end of said piezoelectric element along an expanding/contracting direction thereof;
a movable member frictionally engaging on said driving member;
a voltage applying circuit for applying a rectangular wave signal to said piezoelectric element; and
a series circuit containing a capacitive element for removing an DC component of said rectangular wave signal and an inductive element connected in series thereto, said series circuit being provided between said voltage applying circuit and said piezoelectric element, wherein
said actuator moves said driving member and said movable member relative to each other by applying said rectangular wave signal to said piezoelectric element and thereby causing expanding/contracting displacements expanding and contracting at respectively different speeds in said driving member.

13. An actuator comprising:
an element array constructed by connecting a plurality of piezoelectric elements, each expanding and contracting by application of a driving signal, along an expanding/contracting direction thereof;
a driving member fixed to one end of said element array along said expanding/contracting direction thereof;
a movable member frictionally engaging on said driving member;
a voltage applying circuit which, by dividing said element array into a plurality of piezoelectric element units each consisting of one or more piezoelectric elements, applies a first sinusoidal wave signal to each piezoelectric element in a first piezoelectric element unit and applies an n-th sinusoidal wave signal of a frequency n times the frequency of said first sinusoidal wave signal to each piezoelectric element in an n-th piezoelectric element unit, where n is an integer larger than 1; and
an inductive element connected in parallel to each of said plurality of piezoelectric elements and between said voltage applying circuit and said element array, wherein
said actuator moves said driving member and said movable member relative to each other by applying an AC voltage to each of said piezoelectric elements in said element array and thereby causing expanding/contracting displacements expanding and contracting at respectively different speeds in said driving member.
